(19) United States
(12) Patent Application Publication
(10) Pub. No.: US 2024/0102157 A1
(43) Pub. Date: Mar. 28, 2024

(54) PLASMA-ENHANCED MOLYBDENUM DEPOSITION

(71) Applicant: Applied Materials, Inc., Santa Clara, CA (US)

(72) Inventors: TUERXUN AILIHUMAER, Santa Clara, CA (US); Srinivas Gandikota, Santa Clara, CA (US); Yixiong Yang, Fremont, CA (US); Yogesh Sharma, Sunnyvale, CA (US); Ashutosh Agarwal, San Jose, CA (US); Mandyam Sriram, San Jose, CA (US)

(73) Assignee: Applied Materials, Inc., Santa Clara, CA (US)

(21) Appl. No.: 17/950,946

(22) Filed: Sep. 22, 2022

(51) Int. Cl. C23C 16/08; C23C 16/455; H01L 21/285

(52) U.S. Cl. CPC C23C 16/08; C23C 16/45538; C23C 16/45553; H01L 21/28556; H01L 2924/01042

(57) ABSTRACT

Embodiments of the disclosure are directed to methods of depositing a molybdenum film directly on a substrate surface (e.g., a low-K dielectric material) by exposing the substrate surface to a molybdenum-containing precursor and a plasma at a temperature of less than or equal to 400° C. The molybdenum-containing precursor comprises one or more of molybdenum pentachloride (MoCl₅), molybdenum dioxide dichloride (MoO₂Cl₂), molybdenum oxytetrachloride (MoOCl₄), molybdenum hexacarbonyl, bis(tert-butylimido)-bis(dimethylamido)molybdenum, or bis(ethylbenzene) molybdenum. The plasma comprises one or more of hydrogen (H₂), nitrogen (N₂), or a silane (SiₓH_{y}). In some embodiments, when the molybdenum-containing precursor comprises molybdenum hexafluoride (MoF₆), the plasma does not include hydrogen (H₂).

### TECHNICAL FIELD

Embodiments of the present disclosure pertain to the field of electronic device manufacturing, and in particular, to integrated circuit (IC) manufacturing. In particular, embodiments of the disclosure are directed to plasma-enhanced deposition of molybdenum at reduced temperatures.

### BACKGROUND

As circuit integration increases, there is an enhanced need for greater uniformity and process control regarding layer thickness. As a result, various technologies have been developed to deposit layers on substrates in a cost-effective manner, while maintaining control over the characteristics of the layer. Chemical vapor deposition (CVD) is one of the most common deposition processes employed for depositing layers on a substrate.

A variant of CVD that demonstrates excellent step coverage is cyclical deposition or atomic layer deposition (ALD). ALD employs chemisorption techniques to deliver precursor molecules on a substrate surface in sequential cycles. An ALD cycle includes exposing the substrate surface to a first precursor, a purge gas, a second precursor, and the purge gas. The first and second precursors react to form a product compound as a film on the substrate surface. The ALD cycle is repeated to form the layer to a desired thickness.

The advancing complexity of advanced microelectronic devices is placing stringent demands on currently used deposition techniques. Molybdenum and molybdenum-based films have attractive material and conductive properties. These films have been proposed and tested for applications from front-end to back-end parts of semiconductor and microelectronic devices.

While not wishing to be bound by any particular theory or principle, it is believed that molybdenum cannot be deposited and grown directly on a dielectric surface, and that molybdenum can be deposited and grown on a metallic surface.

Molybdenum films may be used as low resistivity electrical connections in the form of vertical interconnects and/or horizontal interconnects through which current flows, as vias between adjacent metal layers, and as contacts between a first metal layer and the devices on a substrate. For example, in both blanket films and in gap fill applications, a liner film (e.g., a TiN liner film) is typically deposited on a dielectric surface to achieve repeatable molybdenum deposition. In gap fill applications, TiN is deposited in the gap to achieve both low resistivity and conformal deposition. Conformal deposition is often required in order to uniformly deposit a metal film over three-dimensional structures including high aspect ratio features.

There is an ongoing need for improved metal liners or metal layers to provide lower resistivity of molybdenum films. Accordingly, there is a need for improved materials and methods for depositing molybdenum films on dielectric surfaces to provide conformal molybdenum deposition having improved film properties.

### SUMMARY

One or more embodiments are directed to a deposition method comprising depositing a molybdenum film directly on a substrate surface by exposing the substrate surface to a molybdenum-containing precursor and a plasma at a temperature of less than or equal to 400° C. In some embodiments, when the molybdenum-containing precursor comprises molybdenum hexafluoride (MoF₆), the plasma does not include hydrogen (H₂).

Additional embodiments are directed to a method of filling a feature formed on a substrate surface. The method of filling the feature comprises depositing a molybdenum film to fill the feature by exposing the feature to a molybdenum-containing precursor and a plasma at a temperature of less than or equal to 400° C. The feature comprises at least one surface defining a via. The via has a bottom surface comprising a metal material and two sidewalls comprising a low-K dielectric material. In some embodiments, when the molybdenum-containing precursor comprises molybdenum hexafluoride (MoF₆), the plasma does not include hydrogen (H₂).

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a cross-sectional isometric view of a processing chamber according to one or more embodiments;

FIG. 2 illustrates a cross-sectional view of a processing chamber according to one or more embodiments;

FIG. 3A illustrates a schematic cross-sectional view of a dielectric layer on a substrate surface according to one or more embodiments;

FIG. 3B illustrates a schematic cross-sectional view of a liner on the dielectric layer on the substrate surface shown in FIG. 3A according to one or more embodiments;

FIG. 3C illustrates a schematic cross-sectional view of a molybdenum film on the liner shown in FIG. 3B according to one or more embodiments;

FIG. 4A illustrates a schematic cross-sectional view of a feature on a substrate according to one or more embodiments;

FIG. 4B illustrates a schematic cross-sectional view of a liner on a dielectric region of the feature on the substrate shown in FIG. 4A according to one or more embodiments; and

FIG. 4C illustrates a schematic cross-sectional view of a molybdenum film on the liner shown in FIG. 4B according to one or more embodiments.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. In some embodiments, the substrate includes one or more of titanium nitride (TiN), titanium silicide (TiSi), a tungsten-titanium silicide alloy, cleaned silicon (Si), boron-doped silicon germanium (SiGeB), cleaned silicon phosphorous (SiP), titanium aluminum (TiAl), ruthenium (Ru), tungsten (W), and molybdenum (Mo). Substrates include, without limitation, semiconductor wafers.

Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

As used herein, the term “substrate surface” refers to any substrate surface upon which a layer may be formed. The substrate surface may have one or more features formed therein, one or more layers formed thereon, and combinations thereof. The shape of the feature can be any suitable shape including, but not limited to, peaks, trenches, and cylindrical vias. As used in this regard, the term “feature” refers to any intentional surface irregularity. Suitable examples of features include but are not limited to trenches which have a top, two sidewalls and a bottom, peaks which have a top and two sidewalls extending upward from a surface, and vias which have sidewalls extending down from a surface with a bottom. In some embodiments, the bottom of a via comprises an open bottom defined or bounded by underlying material, for example, dielectric material, which may also define the two sidewalls, or the underlying material at the bottom may be a conductor such as a metal (e.g., copper), which can be the same as or different from the sidewall material.

As used in this specification and the appended claims, the term “selectively” refers to process which acts on a first surface with a greater effect than another second surface. Such a process would be described as acting “selectively” on the first surface over the second surface. The term “over” used in this regard does not imply a physical orientation of one surface on top of another surface, rather a relationship of the thermodynamic or kinetic properties of the chemical reaction with one surface relative to the other surface.

The term “on” indicates that there is direct contact between elements. The term “directly on” indicates that there is direct contact between elements with no intervening elements.

As used in this specification and the appended claims, the terms “precursor”, “reactant”, “reactive gas” and the like are used interchangeably to refer to any gaseous species that can react with the substrate surface.

As used herein, the term “liner” refers to a layer formed (e.g., conformally formed) along at least a portion of the sidewalls and/or lower surface of an opening such that a substantial portion of the opening prior to the deposition of the layer remains unfilled after deposition of the layer. In some embodiments, the liner may be formed along the entirety of the sidewalls and lower surface of the opening. A liner may also be formed on a flat surface of a flat substrate.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

In one or more embodiments, a liner and/or a film is conformally deposited on a surface. As used herein, the term “conformal”, or “conformally”, refers to a film that adheres to and uniformly covers exposed surfaces with a thickness having a variation of less than 5%, less than 2%, or less than 1% relative to the average thickness of the film. For example, a 1,000 Å thick film may have less than a 10 Å variation in thickness. This thickness and variation includes at least edges, corners, sides, and the bottom of recesses. For example, a conformal film deposited by ALD in various embodiments of the disclosure would provide coverage over the deposited region of essentially uniform thickness on complex surfaces.

Embodiments of the disclosure advantageously provide methods which improve molybdenum film resistivity deposited on an underlying molybdenum layer (e.g., a molybdenum-containing liner) formed by the methods described in this disclosure.

Resistivity is an intrinsic property of a material and a measurement of a material's resistance to the movement of charge through the material. The resistivity of a material affects the electrical operation of an integrated circuit. Low resistivity molybdenum films minimize power losses and overheating in integrated circuit designs. Because the resistivity of the liner layer is typically greater than the resistivity of the bulk material, the thickness of the liner layer should be minimized to keep the total resistance as low as possible. On the other hand, the molybdenum-containing liner should be sufficiently thick to fully cover the underlying substrate to support high quality bulk deposition. For narrow width and/or high aspect ratio and thin features, obtaining thin liners is even more critical.

In addition to providing molybdenum-containing films having low resistivity, the methods described herein provide films having good uniformity and adhesion to the underlying material. One or more embodiments provides methods in which a molybdenum-containing liner is deposited directly on a dielectric surface. The inventors have surprisingly found that a unique combination of molybdenum-containing precursors and plasma allows for molybdenum deposition on a dielectric surface. Further embodiments advantageously provide methods of reducing the stack resistivity of bottom-up gap fill for vias with improved molybdenum film properties.

One or more embodiments are directed to methods of depositing molybdenum films at low temperatures. In some embodiments, the methods advantageously include depositing molybdenum for contacts & multilevel interconnects, as an example, a temperature of less than or equal to 400° C. The molybdenum film may be deposited at a temperature in a range of 250° C. to 400° C. and at a pressure in a range of from 1 Torr to 300 Torr. Without intending to be bound by theory, it is thought that low temperature is critical due to low-K dielectric materials in which trenches and vias are patterned.

It is also thought that high deposition temperature, such as, for example, temperatures greater than 400° C., or greater than 450° C., may lead to mechanical deformation of low-K dielectric materials, faster & higher diffusion of metal atoms or byproducts (HF, HCl etc.) into low-K dielectric materials which changes K-value, breakdown voltage and increases resistive capacitance (RC) delay.

In some embodiments, a molybdenum film is directly deposited on a substrate surface by exposing the substrate surface to a molybdenum-containing precursor and a plasma. In some embodiments, depositing the molybdenum film comprises one or more of atomic layer deposition (ALD), chemical vapor deposition (CVD), or pulsed CVD (pCVD). In some embodiments, the substrate surface is exposed to the molybdenum-containing precursor and the plasma simultaneously. In some embodiments, the substrate surface is exposed to the molybdenum-containing precursor and the plasma sequentially.

In some embodiments, depositing the molybdenum film comprises atomic layer deposition (ALD), which includes one or more cycles of exposing the substrate surface to a first precursor (e.g., the molybdenum-containing precursor), a purge gas, a second precursor (e.g., the plasma), and the purge gas.

In some embodiments, depositing the molybdenum film comprises a spatial ALD process, wherein a first reactive gas (e.g., the molybdenum-containing precursor) and second reactive gas (e.g., the plasma) are delivered simultaneously to the reaction zone but are separated by an inert gas curtain and/or a vacuum curtain. In some embodiments, depositing the molybdenum film comprises co-flowing the molybdenum-containing precursor and the plasma. In some embodiments, depositing the molybdenum comprises chemical vapor deposition (CVD). In some embodiments, depositing the molybdenum film comprises pulsed chemical vapor deposition (pCVD), wherein one or both of the reactants (e.g., the molybdenum-containing precursor and the plasma) is/are pulsed into a processing chamber.

Advantageously, in one or more embodiments, the molybdenum film described herein is deposited in a manner that avoids a gas phase reaction in the reactor (processing chamber) at a temperature of less than or equal to 400° C. Without intending to be bound by theory, it is thought that avoiding gas phase reactions during deposition forms a film having improved conformality and improved film properties. Gas phase reactions of the molybdenum-containing precursor and the plasma may be avoided by implementing a dual channel showerhead comprising a first channel and a second channel, where the molybdenum-containing precursor is flowed through the first channel and the plasma is flowed through the second channel, or vice versa. In some embodiments, the molybdenum-containing precursor and the plasma are dispensed symmetrically close to a wafer (or substrate) to avoid a gas phase reaction. In some embodiments, a gas phase reaction may be avoided by depositing the molybdenum film using a spatial ALD process, wherein the first reactive gas (e.g., the molybdenum-containing precursor) and the second reactive gas (e.g., the plasma) are delivered simultaneously to the reaction zone but are separated by an inert gas curtain and/or a vacuum curtain.

The molybdenum-containing precursor may comprise any suitable molybdenum-containing compound. In some embodiments, the molybdenum-containing precursor comprises one or more of molybdenum pentachloride (MoCl₅), molybdenum dioxide dichloride (MoO₂Cl₂), molybdenum oxytetrachloride (MoOCl₄), molybdenum hexacarbonyl, bis(tert-butylimido)-bis(dimethylamido)molybdenum, or bis(ethylbenzene) molybdenum.

The plasma may comprise any suitable plasma known to the skilled artisan. In some embodiments, the plasma comprises one or more of hydrogen (H₂), nitrogen (N₂), or a silane (SiₓH_{y}). The plasma may be generated by any suitable plasma source known to the skilled artisan. In some embodiments, the plasma is generated by a plasma source selected from one or more of a capacitively coupled plasma (CCP) source, an inductively coupled plasma (ICP) source, a microwave plasma source, or a remote plasma source.

In one or more embodiments, an ion filter separates one or more plasma sources. In one or more embodiments, the ion filter is used to filter ions from the plasma effluents during transit from the plasma source to the substrate surface. In one or more embodiments, the ion filter functions to reduce or eliminate ionically charged species traveling from the plasma source to the substrate surface. In one or more embodiments, uncharged neutral and radical species may pass through at least one aperture in the ion filter to react at the substrate surface. It should be noted that complete elimination of ionically charged species surrounding the substrate surface is not always the desired goal. In one or more embodiments, ionic species are required to reach the substrate surface in order to perform etch and/or deposition processes. In these instances, the ion filter helps control the concentration of ionic species in a region surrounding the substrate surface at a level that assists the treat/clean and/or deposition process. Without intending to be bound by theory, it is thought that using the ion filter may improve conformality of the deposition of the molybdenum films. In one or more embodiments, the ion filter comprises a showerhead. In some embodiments, the showerhead is a dual channel showerhead, such as the dual channel showerhead described herein.

In one or more specific embodiments, when the molybdenum-containing precursor comprises molybdenum hexafluoride (MoF₆), the plasma does not include hydrogen (H₂). It is thought that when the molybdenum-containing precursor comprises molybdenum hexafluoride (MoF₆) and the plasma includes hydrogen (H₂), the reactants can be used to thermally deposit molybdenum films at temperatures greater than or equal to 400° C., but the reaction generates a large amount of hydrofluoric acid (HF) which can have detrimental effects on low-K dielectric materials.

In some embodiments, the methods further comprise depositing a molybdenum-containing liner directly on the substrate surface (e.g., the dielectric material). In embodiments where the molybdenum-containing liner is present, the molybdenum-containing liner is formed by one or more of atomic layer deposition (ALD), chemical vapor deposition (CVD), or pulsed CVD (pCVD). In embodiments where the molybdenum-containing liner is present, the molybdenum-containing liner is formed by exposing the dielectric surface to a molybdenum-containing precursor and a plasma comprising a mixture of ammonia (NH₃) and silane (SiH₄). In some embodiments, the molybdenum-containing liner comprises one or more of molybdenum nitride (MoNₓ) or molybdenum silicide (MoSiₓ).

In some embodiments, the methods further comprise depositing a molybdenum-containing liner directly on a bottom surface and two sidewalls of a feature formed in a substrate. In embodiments where the molybdenum-containing liner is present, the molybdenum-containing liner is formed by one or more of atomic layer deposition (ALD), chemical vapor deposition (CVD), or pulsed CVD (pCVD). In embodiments where the molybdenum-containing liner is present, the molybdenum-containing liner is formed by exposing the bottom surface and the two sidewalls to a molybdenum-containing precursor and a plasma comprising a mixture of ammonia (NH₃) and silane (SiH₄). In some embodiments, the molybdenum-containing liner comprises one or more of molybdenum nitride (MoNₓ) or molybdenum silicide (MoSiₓ).

Further embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

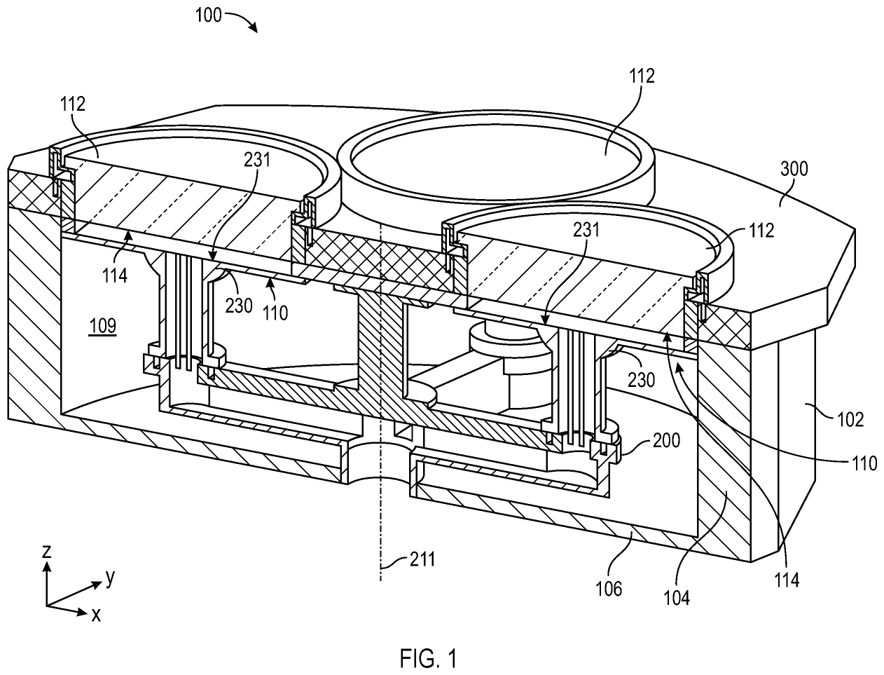

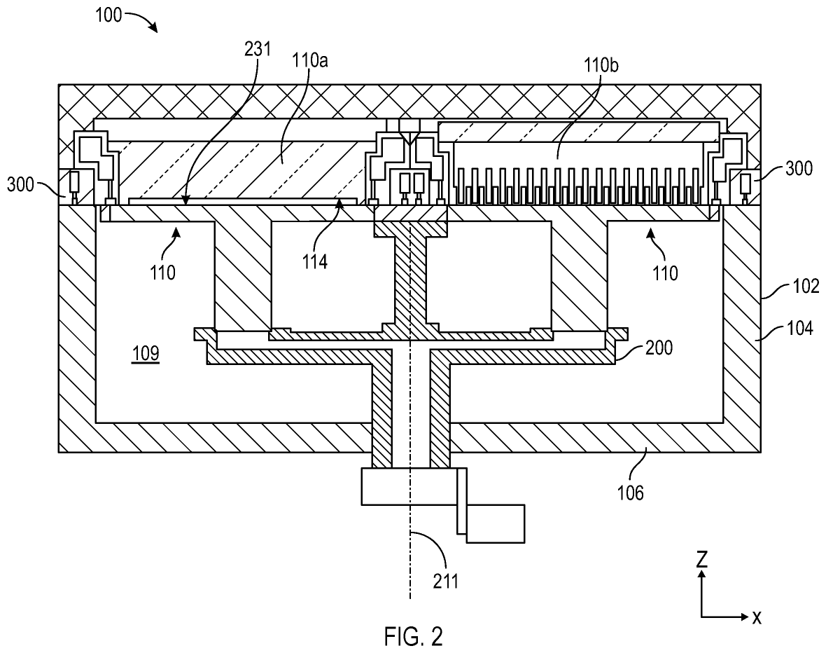

FIG. 1 illustrates a cross-sectional isometric view of a processing chamber according to one or more embodiments. FIG. 2 illustrates a cross-sectional view of a processing chamber according to one or more embodiments. The processing chambers shown in FIGS. 1 and 2 will be described further below.

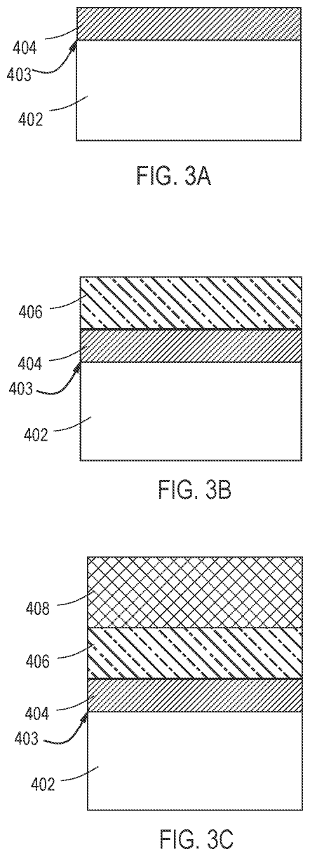

FIGS. 3A-3C depict cross-sectional views of a deposition process on a substrate according to one or more embodiments which produces low electrical resistivity films on a dielectric layer. Referring first to FIG. 3A, a substrate 402 is shown, having a surface such as top surface 403 and a dielectric layer 404 on the top surface 403. Referring to FIG. 3B, in one or more embodiments, an optional liner 406 is shown directly on the dielectric layer 404 on the top surface 403 of the substrate 402. Referring to FIG. 3C, in one or more embodiments, a molybdenum film 408 is shown on the liner 406.

The substrate 402 can be any suitable substrate material. In one or more embodiments, the substrate 402 comprises a semiconductor material, e.g., silicon (Si), carbon (C), germanium (Ge), silicon germanium (SiGe), gallium arsenide (GaAs), indium phosphate (InP), indium gallium arsenide (InGaAs), indium aluminum arsenide (InAlAs), germanium (Ge), silicon germanium (SiGe), other semiconductor materials, or any combination thereof. In one or more embodiments, the substrate 402 comprises one or more of silicon (Si), germanium (Ge), gallium (Ga), arsenic (As), indium (In), phosphorus (P), or selenium (Se). In some embodiments, the substrate 402 comprises one or more of titanium nitride (TiN), titanium silicide (TiSi), a tungsten-titanium silicide alloy, cleaned silicon (Si), boron-doped silicon germanium (SiGeB), cleaned silicon phosphorous (SiP), titanium aluminum (TiAl), ruthenium (Ru), tungsten (W), and molybdenum (Mo). Although a few examples of materials from which the substrate 402 may be made have been provided, any material that may serve as a foundation upon which passive and active electronic devices (e.g., transistors, memories, capacitors, inductors, resistors, switches, integrated circuits, amplifiers, optoelectronic devices, or any other electronic devices) may can be utilized.

In some embodiments, the substrate 402 may include dielectric materials, for example, silicon-containing dielectric materials and/or metal oxide dielectric materials. In some embodiments, the substrate 402 may comprise one or more dielectric surfaces (such as dielectric layer 404) comprising a low-K dielectric material such as, but not limited to, silicon oxide (SiOx), silicon sub-oxides, silicon nitride (SiNₓ), silicon nitride (Si₃N₄), silicon carbide (SiCₓ), silicon oxycarbide (SiOₓC_{y}), silicon carbonitride (SiCₓN_{y}), silicon oxynitride (SiOₓN_{y}), tantalum nitride (TaN), hafnium oxide (HfOₓ), or combinations thereof.

The optional liner 406 may have any suitable thickness. In some embodiments, the liner 406 has a thickness of less than or equal to 20 Å, including, for example, a thickness in a range of from 0.5 Å to 20 Å, 0.5 Å to 15 Å, 0.5 Å to 10 Å, 1 Å to 9 Å, 2 Å to 8 Å, 3 Å to 8 Å, 4 Å to 7 Å, or 5 Å to 6 Å.

In one or more embodiments, the molybdenum film 408 is deposited directly on the liner 406. In one or more embodiments, the molybdenum film 408 is conformally deposited directly on liner 406. The molybdenum film 408 may have any suitable thickness.

Advantageously, the conformally deposited molybdenum film 408 on the liner 406 has a resistivity that is reduced by at least 30% compared to a titanium nitride (TiN) film having a conformally deposited molybdenum film deposited thereon. In some embodiments, the liner 406 and the conformally deposited molybdenum film 408 define a film stack having a resistivity less than or equal to 35 μΩ-cm when the liner 406 and the conformally deposited molybdenum film 408 have a combined thickness of about 100 Å. It has been advantageously found that depositing the molybdenum film using the methods described herein, which includes using plasma such as hydrogen (H₂) radicals, impurities may be removed more efficiently which can further increase film grain size and reduce resistivity. In some embodiments, the resistivity of the film stack when the liner 406 and the conformally deposited molybdenum film 408 have a combined thickness of about 100 Å is in a range of from 15 μΩ-cm to 35 μΩ-cm, including in a range of from 20 μΩ-cm to 35 μΩ-cm, in a range of from 25 μΩ-cm to 35 μΩ-cm, in a range of from 20 μΩ-cm to 25 μΩ-cm, or in a range of from 30 μΩ-cm to 35 μΩ-cm. In some embodiments, the resistivity of the film stack when the liner 406 and the conformally deposited molybdenum film 408 have a combined thickness of about 100 Å is about 31 μΩ-cm.

Another aspect of the disclosure pertains to an electronic device comprising a molybdenum-containing liner on a dielectric surface and a molybdenum film directly on the molybdenum-containing liner. The inventive methods may be utilized with any device nodes, but may be particularly advantageous in device nodes of about 25 nm or less, for example about 5 nm to about 25 nm.

Further aspects of the disclosure pertain to a method that is part of a gap fill process. In some embodiments, a molybdenum-containing liner is deposited on a dielectric surface with one or more high aspect ratio gap features, including vertical gap features and/or horizontal gap features, and the molybdenum in the gap features forms horizontal interconnects through which current flows. Without intending to be bound by theory, gaps filled with molybdenum conformally deposited on the molybdenum-containing liner, according to one or more embodiments of the methods described herein, result in improved electrical operation of an integrated circuit, by minimizing power losses and overheating in the integrated circuit having molybdenum-filled gaps.

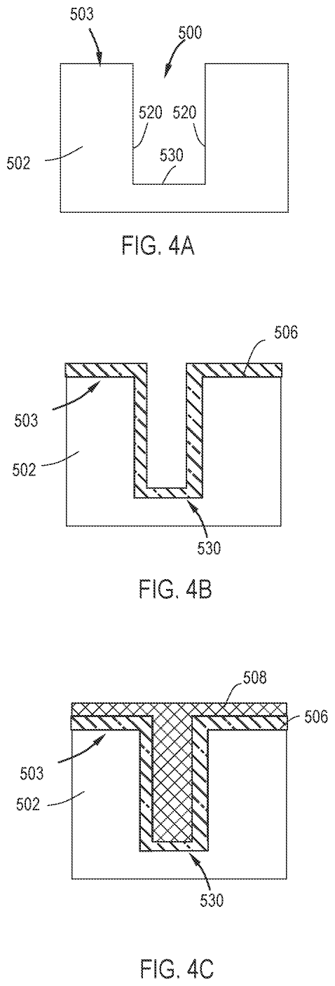

Referring to FIGS. 4A-4C, a method of filling a feature formed on a top surface 503 of a substrate 502 is shown with respect to a feature 500 that has a gap defined by opposed sidewalls 520 and a bottom 530. The substrate 502 can comprise any of the non-limiting materials described above with respect to FIGS. 3A-3C. In the embodiments shown in FIGS. 4A-4C, the substrate 502 comprises a dielectric region.

In one of more embodiments, referring to FIG. 4B, a method of filing the feature comprises forming a molybdenum-containing liner 506 directly on a dielectric region including a top surface 503 within the feature 500 on the surface of the substrate 502, the feature 500 comprising at least one surface defining a via, the via comprising a bottom 530 and two opposed sidewalls 520 comprising the dielectric.

Referring to FIG. 4C, the method comprises conformally depositing a molybdenum film 508 on the molybdenum-containing liner 506 to fill the feature 500, the conformally deposited molybdenum film 508 substantially free of seams or voids. In some embodiments, the molybdenum film 508 is directly deposited on the molybdenum-containing liner 506 by exposing a surface of the molybdenum-containing liner 506 to a molybdenum-containing precursor and a plasma by one or more of atomic layer deposition (ALD), chemical vapor deposition (CVD), or pulsed CVD (pCVD) to fill the feature 500. The surface of the molybdenum-containing liner 506 may be exposed to, for example, one or more ALD cycles includes exposing the surface of the molybdenum-containing liner 506 to a first precursor (e.g., the molybdenum-containing precursor), a purge gas, a second precursor (e.g., the plasma), and the purge gas to form the molybdenum film 508 to a desired thickness to fill the feature 500.

The Figures show a substrate 502 having a single feature 500 for illustrative purposes; however, those skilled in the art will understand that there can be more than one feature 500. The shape of the feature 500 can be any suitable shape including, but not limited to, trenches and cylindrical vias. As used in this regard, the term “feature” means any intentional surface irregularity. Suitable examples of features include, but are not limited to, trenches which have a top, two sidewalls and a bottom, peaks which have a top and two sidewalls extending upward from a surface, and vias which have sidewalls extending down from a surface with a bottom. In some embodiments, the bottom of a via comprises an open bottom defined or bounded by underlying material, for example, dielectric material, which may also define the two sidewalls, or the underlying material at the bottom may be a conductor such as a metal (e.g., copper), which may be different material. In one or more embodiments, the at least one feature 500 comprises one or more of a trench or a via. In specific embodiments, the at least one feature 500 comprises a via. In still further embodiments, the term “at least one feature 500” and “via 500” may be used interchangeably. The via 500 has a depth to the bottom 530 and a width between the two opposed sidewalls 520. In some embodiments, the depth is in a range of 2 nm to 200 nm, 3 nm to 200 nm, 5 nm to 100 nm, 2 nm to 100 nm, or 50 nm to 100 nm. In some embodiments, the width is in a range of 10 nm to 100 nm, 10 nm to 20 nm, 10 nm to 50 nm, or 50 nm to 100 nm. In some embodiments, the via 500 has an aspect ratio (depth/width) in a range of 1:1 to 20:1, 5:1 to 20:1, 10:1 to 20:1, or 15:1 to 20:1.

The methods described herein may be performed in any suitable processing chamber known to the skilled artisan. The methods described herein may be performed in, for example, an atomic layer deposition (ALD) processing chamber (including a spatial ALD processing chamber), a chemical vapor deposition (CVD) processing chamber, or a pulsed CVD (pCVD) processing chamber. The processing chamber or processing chamber platform may include, but is not limited to: Continuum®, Olympia®, Tesseract™, PRODUCER® systems and any related PRODUCER platforms, PRECISION 5000® systems, Trillium®, and/or a Selectra™ Etch chamber, all available from Applied Materials, Inc., of Santa Clara, Calif. In some embodiments, the processing chamber includes the Selectra™ Etch chamber which includes a plasma generating source and molybdenum precursor source for flowing the molybdenum-containing precursor. In some embodiments, the entire processing chamber or portions thereof is nickel coated to reduce unwanted particle formation.

In one or more embodiments, the processing chamber comprises a pedestal. The pedestal comprises a heater and an electrostatic chuck. In some embodiments, the pedestal comprises a high current electrostatic chuck at a temperature in a range of from about 200° C. to about 550° C., including a range of from about 200° C. to about 300° C. In one or more embodiments, the pedestal within the processing chamber supports a substrate.

In some embodiments, portions of the processing chamber and/or the substrate are coated with molybdenum prior to exposing the molybdenum-coated portions to the plasma.

The disclosure provides methods for use with single wafer or multi-wafer (also referred to as batch) process chambers. FIGS. 1 and 2 illustrate a processing chamber 100 according to one or more embodiments of the disclosure. FIG. 1 shows the processing chamber 100 illustrated as a cross-sectional isometric view. FIG. 2 shows a processing chamber 100 in cross-section. Accordingly, some embodiments of the disclosure are directed to processing chambers 100 that incorporate a substrate support 200.

The processing chamber 100 has a housing 102 with walls 104 and a bottom 106. The housing 102 along with the top plate 300 define a processing volume 109, also referred to as an interior volume. In some embodiments, portions of the processing volume 109 or the entire processing volume 109 is nickel coated to reduce unwanted particle formation. In some embodiments, the processing chamber 100 comprises a plasma source (not shown) on the top plate 300. In some embodiments, the plasma source comprises one or more of a capacitively coupled plasma (CCP) source, an inductively coupled plasma (ICP) source, a microwave plasma source, or a remote plasma source. In some embodiments, the processing chamber includes the Selectra™ Etch chamber which includes a plasma generating source (not shown) on the top plate 300 and a molybdenum precursor source for flowing the molybdenum-containing precursor.

The processing chamber 100 illustrated includes a plurality of processing stations 110. The processing stations 110 are located in the interior volume 109 of the housing 102 and are positioned in a circular arrangement around the rotational axis 211 of the substrate support 200. Each processing station 110 comprises a gas distribution plate 112 (also referred to as a gas injector) having a front surface 114. In some embodiments, the front surfaces 114 of each of the gas injectors 112 are substantially coplanar. The processing stations 110 are defined as a region in which processing can occur. For example, in some embodiments, a processing station 110 is defined as a region bounded by the support surface 231 of the substrate support 200, as described below, and the front surface 114 of the gas injectors 112. In the illustrated embodiment, heaters 230 act as the substrate support surfaces and form part of the substrate support 200.

The processing stations 110 can be configured to perform any suitable process and provide any suitable process conditions. The type of gas distribution plate 112 used will depend on, for example, the type of process being performed and the type of showerhead or gas injector. For example, a processing station 110 configured to operate as an atomic layer deposition apparatus may have a showerhead or vortex type gas injector. In some embodiments, the processing station 110 comprises a dual channel showerhead as described herein. In some embodiments, portions of the dual channel showerhead or the entire dual channel showerhead is nickel coated to reduce unwanted particle formation. Whereas a processing station 110 configured to operate as a plasma station may have one or more electrode and/or grounded plate configuration to generate a plasma while allowing a plasma gas to flow toward the wafer. The embodiment illustrated in FIG. 2 has a different type of processing station 110 on the left side (processing station 110a) of the drawing than on the right side (processing station 110b) of the drawing. Suitable processing stations 110 include, but are not limited to, thermal processing stations, microwave plasma, three-electrode CCP, ICP, parallel plate CCP, UV exposure, laser processing, pumping chambers, annealing stations and metrology stations.

In some embodiments, the operations of the methods described herein are each performed within the same processing chamber. In some embodiments, the operations of the methods described herein are each performed within a different processing chamber. In some embodiments, the different processing chambers are connected as part of a processing system. In some embodiments, the operations of the methods described herein are performed without an intervening vacuum break.

In some embodiments, one or more of the operations of the methods described herein is performed in situ without breaking vacuum. In some embodiments, one or more of the operations of the methods described herein is performed ex situ. As used herein, the term “in situ” refers to operations of the methods described herein that are each performed in the same processing chamber or a different processing chamber that is connected as part of a processing system, such that each of the operations of the methods described herein are performed without an intervening vacuum break. As used herein, the term “ex situ” refers to operations of the methods described herein that are each performed in the same processing chamber or a different processing chamber such that one or more of the operations of the methods described herein are performed with an intervening vacuum break.

In some embodiments, the molybdenum film 508 is laterally bounded by the two opposed sidewalls 520 of the at least one feature 500. As used in this regard, “laterally bounded” means that the deposited material does not extend beyond the point of intersection between the top surface 503 and the two opposed sidewalls 520. In some embodiments, the molybdenum film 508 extends above the at least one feature 500. In some embodiments, the molybdenum film 508 fills the via 500. As used in this regard, a film which “fills the via” has a volume which occupies at least 95%, at least 98%, or at least 99% of the volume of the via 500. In some embodiments, the molybdenum film 508 which fills the via 500 has a fill height in a range of from 30 nm to 75 nm, including in a range of from 40 nm to 60 nm.

Embodiments of the disclosure advantageously provide molybdenum films 408 having reduced resistivity compared to molybdenum films deposited by processes other than those described herein. Embodiments of the disclosure advantageously provides molybdenum films 508 that are free or substantially free of voids and seams. As used in this regard, “substantially free” means that less than about 5%, including less than about 4%, less than about 3%, less than about 2%, less than about 1%, less than about 0.5%, and less than about 0.1% of the total composition of the conformally deposited molybdenum film 508, on an atomic basis, comprises voids and/or seams.

One or more embodiments of the disclosure are directed to a non-transitory computer readable medium including instructions, that, when executed by a controller of a processing chamber, cause the processing chamber to perform the methods described herein. In some embodiments, the non-transitory computer readable medium includes instructions, that, when executed by a controller of a processing chamber, cause the processing chamber to: deposit a molybdenum film directly on a substrate surface by exposing the substrate surface to a molybdenum-containing precursor and a plasma at a temperature of less than or equal to 400° C. In some embodiments, the non-transitory computer readable medium includes instructions, that, when executed by a controller of a processing chamber, cause the processing chamber to: deposit a molybdenum-containing liner directly on the substrate surface below the molybdenum film.

In some embodiments, the non-transitory computer readable medium includes instructions, that, when executed by a controller of a processing chamber, cause the processing chamber to: deposit a molybdenum film to fill a feature by exposing the feature to a molybdenum-containing precursor and a plasma at a temperature of less than or equal to 400° C., the feature comprising at least one surface defining a via, the via comprising a bottom surface comprising a metal material and two sidewalls comprising a low-K dielectric material. In some embodiments, the non-transitory computer readable medium includes instructions, that, when executed by a controller of a processing chamber, cause the processing chamber to: deposit a molybdenum-containing liner directly on the bottom surface and the two sidewalls.

Reference throughout this specification to “one embodiment,” “certain embodiments,” “one or more embodiments” or “an embodiment” means that a particular feature, structure, material, or characteristic described in connection with the embodiment is included in at least the embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

1. A deposition method comprising:
depositing a molybdenum film directly on a substrate surface by exposing the substrate surface to a molybdenum-containing precursor and a plasma at a temperature of less than or equal to 400° C., wherein the substrate surface comprises a low-κ dielectric material including one or more of silicon oxide (SiO₂), silicon nitride (Si₃N₄), silicon oxynitride (SiON), silicon oxycarbide (SiOC), silicon oxycarbonitride (SiOCN), or silicon carbonitride (SiCN), the molybdenum-containing precursor includes one or more of molybdenum pentachloride (MoCl₆), molybdenum dioxide dichloride (MoO₂Cl₂), molybdenum oxytetrachloride (MoOCl₄), molybdenum hexacarbonyl, molybdenum hexafluoride (MoF₅), bis(tert-butylimido)-bis(dimethylamido)molybdenum, or bis(ethylbenzene) molybdenum, the plasma includes one or more of hydrogen (H₂), nitrogen (N₂), or a silane (SiₓH_{y}), and when the molybdenum-containing precursor comprises molybdenum hexafluoride (MoF₆), the plasma does not include hydrogen (H₂), and depositing the molybdenum film comprises a spatial ALD process where the molybdenum-containing precursor and the plasma are delivered simultaneously to a reaction zone and are separated by an inert gas curtain and/or a vacuum curtain.

2. (canceled)

3. (canceled)

4. (canceled)

5. (canceled)

6. (canceled)

7. The deposition method of claim 1, wherein the molybdenum film is deposited at a temperature in a range of 250° C. to 400° C. and at a pressure in a range of from 1 Torr to 300 Torr.

8. (canceled)

9. (canceled)

10. The deposition method of claim 1, wherein the plasma is generated by a plasma source selected from one or more of a capacitively coupled plasma (CCP) source, an inductively coupled plasma (ICP) source, a microwave plasma source, or a remote plasma source.

11. The deposition method of claim 2, wherein the substrate surface comprises a feature formed therein, the feature having at least one surface defining a via, the via comprising a bottom surface and two sidewalls comprising the low-κ dielectric material.

12. The deposition method of claim 11, further comprising depositing the molybdenum film to fill the feature.

13. A method of filling a feature formed on a substrate surface, the method comprising:
depositing a molybdenum film to fill the feature by exposing the feature to a molybdenum-containing precursor and a plasma at a temperature of less than or equal to 400° C., the feature comprising at least one surface defining a via, the via comprising a bottom surface comprising a metal material and two sidewalls comprising a low-κ dielectric material including one or more of silicon oxide (SiO₂), silicon nitride (Si₃N₄), silicon oxynitride (SiON), silicon oxycarbide (SiOC), silicon oxycarbonitride (SiOCN), or silicon carbonitride (SiCN), the molybdenum film deposited directly on the bottom surface and the two sidewalls,
wherein the molybdenum-containing precursor includes one or more of bis(tert-butylimido)-bis(dimethylamido)molybdenum or bis(ethylbenzene) molybdenum, and the plasma includes one or more of hydrogen (H₂), nitrogen (N₂), or a silane (SiₓH_{y}).

14. (canceled)

15. The method of claim 13, wherein the plasma is generated by a plasma source selected from one or more of a capacitively coupled plasma (CCP) source, an inductively coupled plasma (ICP) source, a microwave plasma source, or a remote plasma source.

16. The method of claim 15, wherein the plasma source comprises an ion filter.

17. The method of claim 13, wherein depositing the molybdenum film comprises one or more of atomic layer deposition (ALD), chemical vapor deposition (CVD), or pulsed CVD (pCVD).

18. (canceled)

19. (canceled)

20. The method of claim 13, wherein exposing the feature to the molybdenum-containing precursor and the plasma comprises flowing the molybdenum-containing precursor and the plasma through a dual channel showerhead comprising a first channel and a second channel, the molybdenum-containing precursor flowed through the first channel and the plasma flowed through the second channel.

21. The method of claim 17, wherein depositing the molybdenum film comprises an atomic layer deposition (ALD) process, the ALD process including exposing the substrate surface on a single pedestal to a pulse of the molybdenum-containing precursor, a purge gas, the plasma, and the purge gas.
